(19) United States
(12) Patent Application Publication
(10) Pub. No.: US 2016/0359060 A1
(43) Pub. Date: Dec. 8, 2016

(54) PREPARATION OF SEMICONDUCTOR FILMS

(71) Applicant: MERCK PATENT GMBH, Darmstadt (DE)

(72) Inventors: Ranjan Deepak DESHMUKH, Watertown, MA (US); Rebekah HOOKER, Belmont, MA (US); Pawel MISKIEWICZ, Southampton (GB); Joerg SCHNEIDER, Seeheim-Jugenheim (DE); Mathias NOWOTNY, Ober-Ramstadt (DE)

(73) Assignee: Merck Patent GmbH, Darmstadt (DE)

(21) Appl. No.: 15/114,897

(22) PCT Filed: Jan. 14, 2015
(86) PCT No.: PCT/EP2015/000049

§ 371 Date: Jul. 28, 2016

Related U.S. Application Data
(60) Provisional application No. 61/934,056, filed on Jan. 31, 2014.

(51) Int. Cl. H01L 31/032; H01L 31/0296; C09D 5/24; C09D 11/52; C01G 49/06; C01G 3/02; C01F 7/30; C01G 15/00; C01G 9/02; C01G 19/02; C01G 19/00; C07F 15/02; C07F 1/08; C07F 5/06; C07F 5/00; C07F 3/06; C07F 7/22; H01L 31/18

(52) U.S. Cl. CPC H01L 31/0322; H01L 31/1864; H01L 31/032; H01L 31/0296; H01L 31/0324; H01L 31/0326; C09D 5/24; C09D 11/52; C01G 49/06; C01G 3/02; C01F 7/30; C01G 15/00; C01G 9/02; C01G 19/02; C01G 19/006; C07F 15/025; C07F 1/08; C07F 5/069; C07F 5/003; C07F 3/06; C07F 7/2244; C01P 2006/40

(57) ABSTRACT

This invention relates to a precursor material, which can be decomposed to form semiconductors and metal oxides, or more generally, materials for electronic components. The precursors comprise metal complexes of hydroxamato ligands. The invention further relates to a preparation process for thin inorganic films comprising various metals (e.g. Cu/In/Zn/Ga/Sn) and oxygen, selenium and/or sulfur. The thin films can be used in photovoltaic panels (solar cells), other semiconductor or electronic devices, and other applications using such films. The process uses molecular, metal containing precursor complexes with hydroxamato ligands. These can be combined in the process with chalcogenide sources or oxygen. Exemplarily, various metal oxides and copper-based chalcopyrites of the I-III-VI₂ type are prepared with high purity at low temperatures.

This invention relates to a precursor material, which can be decomposed to form semiconductors and metal oxides, or more generally, materials for electronic components. The precursors comprise metal complexes of hydroxamato ligands. The invention further relates to a preparation process for thin inorganic films comprising various metals (e.g. Cu/In/Zn/Ga/Sn) and oxygen, selenium and/or sulfur. The thin films can be used in photovoltaic panels (solar cells), other semiconductor or electronic devices, and other applications using such films. The process uses molecular, metal containing precursor complexes with hydroxamato ligands. These can be combined in the process with chalcogenide sources or oxygen. Exemplarily, various metal oxides and copper-based chalcopyrites of the I-III-VI₂ type are prepared with high purity at low temperatures.

### INTRODUCTION AND BACKGROUND

Photovoltaic panels are normally made of either crystalline silicon or thin-film cells. Many currently available solar cells are configured as bulk materials that are subsequently cut into wafers and treated in a “top-down” method of synthesis, with silicon being the most prevalent bulk material. In an attempt to make cheaper panels, other materials are configured as thin-films (inorganic layers, organic dyes, and organic polymers) that are deposited on supporting substrates.

I-III-VI₂-type copper-based semiconductors (chalcopyrite-type) like CuInSe₂ (CIS), CuIn(S_{y}, Se_{1-y})₂ (CISS), CuInₓGa₁₋ₓ(Se_{y}, S_{1-y})₂ (CIGS) are being widely studied semiconductors as an absorber layer for thin film solar cells. CISS and CIGS have a direct bandgap that is tuneable by varying the In/Ga ratio or by varying the S/Se ratio to match the solar spectrum.

CIGS is one of the most promising semiconductors capable to reaching 20.3% power conversion efficiency in a thin film solar cell device, comparable to multicrystalline solar cells (Green et al., Prog. Photovoltaics, 2012, 20, 12). The Cu(Zn,Sn)(S,Se)₄ (CZTS) based solar cell is another promising low cost alternative that utilizes cheaper and earth abundant elements, with best reported solar cell efficiency of about 11.1% (Todorov et al. Adv. Energy Mat., 2013, 3, 34-38).

Solution processing of CIGS and CZTS offer a potential for cost reduction as compared to vacuum based techniques. The high efficiency CIGS devices are usually prepared using a complex vacuum based process i.e. 3-stage co-evaporation of metals under a constant source of selenium. For the large scale production, the challenges include composition uniformity over large areas, precise control of flux/deposition rates to avoid intermediate phases and low material utilization (material also deposits on walls of the vacuum chamber). Solution based deposition methods can provide several advantages over vacuum based processes such as high material utilization, excellent compositional uniformity, cost cutting roll-to-roll mass production. (Hibberd et al., Prog. Photovolt: Res. Appl., 2010 18: 434). In addition to the above-mentioned advantages, several solution based techniques could be used for depositing absorber layer such as spraying, spin coating, ink jet printing, doctor blading, slot coating, flexographic/gravure coating, drop casting, dip coating etc.

The absorber layer can be solution processed using a particle based ink or precursor based ink or a mixture of both. A 12.0% efficient device has been demonstrated by conversion of Cu(In,Ga)S₂ nanoparticle film to Cu(In,Ga)(S,Se)₂ by annealing under selenium vapor (Guo et al., Prog. Photovolt: Res. Appl. 2012, DOI: 10.1002/pip.2200). Kapur et al. deposited a low-cost metal oxide particle ink, followed by reduction under hydrogen and selenization to achieve a 13.6% device efficiency (Kapur et al. Proceedings of 33^{rd} IEEE photovoltaic Specialists conference, San Diego 2008). Nanosolar utilized binary metal selenides nanoparticles to achieve 15% efficient device (17^{th} International Photovoltaic Science and Engineering Conference, Nanosolar Inc., Tokyo, Japan, 2007).

IBM has demonstrated 15.2% efficient CIGS device by processing a precursor ink made by dissolving metal selenides and sulfides in hydrazine (Todorov et al. Prog. Photovolt: Res. Appl., 2012, DOI: 10.1002/pip.1253, US 20090145482A1, US 20090121211, WO 1997023004). However hydrazine is highly toxic and flammable that could limit the use of this method in a large scale manufacturing environment. Spray pyrolysis of metal salts like CuCl, InCl₃, GaCl₃ with selenourea or thiourea and their derivatives is also shown to produce metal chalcogenide films. The drawback of this approach is the high residual amounts of chlorine and oxide phases in the films leading to poor photovoltaic performance (Hibberd et al., Prog. Photovolt: Res. Appl., 2010 18: 434; WO 8810513; JP 3068775A). Madar'asz et al. reported that aqueous based mixtures of thiourea complexes of Cu, Zn, Sn could be spray pyrolyzed to prepare copper zinc tin sulfide (CZTS) films (Solid State Ionics 141-142, 2001, 439-446). Thermal decomposition of organometallic precursors for preparing metal chalcogenides has also been previously reported. (JP 01-298010 A, JP 2001274176, JP 11004009A). Fujdala et al. (US 2011/0030786 A1) reported synthesis of Cuₓ(In_{1-y}Ga_{y})ᵥ((S_{1-z}Se_{z})_{R})_{w} polymeric precursor where elemental ratio and number of repeat units w could be varied and R represents an organic or inorganic ligand. Wang et al. dissolved metal oxides in butyldithiocarbamic acid, forming thermally degradable organometallic molecular precursor inks. Using these inks Cu(In,Ga)(S,Se)₂ thin film solar cells exhibited an average efficiency up to 8.8% (Wang et al. Chem. Mater. 2012, 24, 3993).

Owing to the true solution nature of the precursor inks, a precise control over elemental composition can be achieved as compared to the nanoparticle route. (Wang et al. Chem. Mater. 2012, 24, 3993) There still exists a need for ternary or multinary metal chalcogenide materials which can be transformed smoothly into semiconductor films with highly crystalline morphology and good solar energy conversion.

For industrial processes the materials and compositions used for the production of semiconductor layers should be stable, cost-efficient, environmental benign, and easy to handle without exposure to excessive hazards.

The preparation of amorphous, semiconducting oxide ceramics is also of interest (K. Nomura et al. Nature 2004, 432, 488-492; H. Hosono Journal of Non-Crystalline Solids 2006, 352, 851-858; T. Kamiya et al. Journal of Display Technology 2009, 5, 273-288). The indium-gallium-tin-zinc-oxygen phase system has been investigated in detail here. Typical examples are indium gallium zinc oxide (abbreviated to “IGZO”), and zinc tin oxide (abbreviated to “ZTO”), but also indium zinc tin oxide (abbreviated to “IZTO”).

The deposition of semiconducting layers is often carried out via the gas phase, but processes based on solutions are also known. However, the sols employed here make relatively high processing temperatures necessary. Zinc tin oxide can be obtained from anhydrous tin(II) chloride or tin(II) acetate and zinc acetate hexahydrate in the presence of bases, such as ethanolamine. The conversion to the oxide (with oxidation of the tin components) is carried out at 350° C. and above (D. Kim et al. Langmuir 2009, 25, 11149-11154) or 400-500° C. (S. J. Seo et al. Journal of Physics D: Applied Physics, 2009, 42, 035106), depending on the reaction performance during calcination, in air. Indium zinc tin oxide is obtained from anhydrous indium chloride, zinc chloride and tin(II) chloride in ethylene glycol by reaction with sodium hydroxide solution and subsequent calcination at 600° C. (D. H. Lee et al. Journal of Materials Chemistry 2009, 19, 3135-3137).

Some metal complexes with hydroxamate ligands have been noted in prior art. In GB 894,120 ferric pivalhydroxamate (C₁₅H₃₀O₆N₃Fe) and cupric pivalhydroxamate (C₁₀H₂₀O₄N₂Cu) are mentioned as isolated substances.

### DEFINITIONS

The term “chalcogen” according to this disclosure is limited to sulfur (S), selenium (Se) and to some degree tellurium (Te). Selenium (Se), sulfur (S) and combinations of S and Se are preferred chalcogens. A “chalcogen source” is any type of chalcogen or chalcogen containing compound(s).

The term “metal chalcogenide” stands for metal sulfides, metal selenides or metal tellurides, and their combinations.

The term “metal” stands for metals including main group metals, transition metals, lanthanides and germanium.

A “binary” chalcogenide is one that is composed of a single metal and a chalcogenide, such as In₂S₃ or Cu₂Se. A “ternary” chalcogenide means a material composed of two metals and chalcogenide, like CIS (CuInS₂) or CISS (CuIn(S,Se)₂). A “quaternary” chalcogenide analogously stands for a material consisting of three metals and chalcogenide, like CIGS. “Multinary” chalcogenides stand analogously for a material consisting of even more metals.

Chalcogenide semiconductors used throughout this disclosure are referenced by their types according to their elemental composition. The numbers I (for e.g. Cu, Ag), II (for e.g. Zn, Cd), III (for e.g. Al, Ga, In), IV (for e.g. Ge, Sn) and VI (for e.g. S, Se, Te) are used standing for a certain group of elements, here added in brackets, with the same number of valency electrons. Accordingly a “I-III-VI” type semiconductor usually means a ternary chalcogenide mainly comprising metals from the groups 11 (aka IB) and 13 (aka IIIA), and chalcogenide (group 16). Likewise, a “I-II/IV-VI” type semiconductor means a quaternary chalcogenide mainly comprising metals from the groups 11 (aka IB) and 12 (aka IIB), 14 (aka IVA) and chalcogenide (group 16, aka VIA). The stoichiometry varies around the values usually found in this type of semiconducting chalcogenides. The idealistic stoichiometric formulae like e.g. CuInS₂ or Cu₂ZnSnSe₂ can be varied significantly by interchanging metals of different groups.

The terms “CIGS” and “CZTS” are generally used throughout this disclosure in analogy to the common understanding in literature. CIGS stands for copper indium gallium selenide/sulfide of varying elemental distribution, including the presence of other elements in a smaller amount. CZTS stands for copper zinc tin selenide of varying elemental distribution. The compounds are often described alternatively by a variable molecular formula like Cu(In,Ga)(S, Se)₂ and Cu₂ZnSn(S,Se)₄. The elements combined in brackets indicate any of the elements or a combination of them, while the combined amount is in accordance with the stoichiometric requirements of the formula. Exemplary (S,Se)ₙ stands for Sₙ₋ₓSeₓ, and x is a numerical value between 0 and n. For example, when n is 2, x can stand for 0, 0.1, 0.2, 0.5, 1.0, 1.5, 1.8, 1.9 or 2.0. In general copper poor elemental compositions deviating from the typical stoichiometry are used practically, because they show advantageous absorber characteristics. In that sense the molecular formulae throughout this disclosure include such variations in the elemental distribution. In both kinds of absorbers, CIGS and CZTS, sulfur in replacement of selenium, or vice versa, partly or fully, can be present. In lesser amounts other elements can be present, e.g. Ag replacing Cu, or Sn, Zn, Cd in CIGS, or In, Ge, Cd in CZTS, trace elements like Na, Sb, Te, As, etc.

The term “hydroxamato ligand” used throughout this disclosure is a anionic ligand comprising a structure R¹—(C═O)—N(R²)—O⁽⁻⁾, wherein the groups R¹ and R² are common organic residues. The ligands are derived from hydroxamic acids and N-substituted hydroxamic acids by deprotonation. The ligands can bind through this central structure as a bidentate chelate ligand, using the oxygen atoms as binding centers.

### SUMMARY

Surprisingly, a process has now been developed in which a novel metal complex precursor material is provided, applied to surfaces and subsequently converted at low temperatures into a material for photovoltaic or other electronic applications. The layers produced in the process are distinguished by surface properties which are advantageous for a printing process.

In one aspect of the invention new metal complexes comprising hydroxamato ligands are provided. Metals, to which the hydroxamato ligands are bound, include, but are not limited to, indium (In), gallium (Ga), zinc (Zn), tin (Sn), aluminium (Al), germanium (Ge), Yttrium (Y), Lutetium (Lu) and Europium (Eu), further iron (Fe), copper (Cu) and cadmium (Cd).

In one aspect of the invention a process for the production of a semiconductor is presented, which is characterized in that
a. precursors comprising one or more metal complexes and a chalcogen source are combined, at least one metal complex comprising at least one hydroxamato ligand, and
b. the combined precursors are decomposed, preferably in an inert environment, by heating or radiation with formation of the semiconductor.

In another aspect of the invention a process for the production of a metal oxide is presented, which is characterized in that

precursors comprising a metal complex comprising at least one hydroxamato ligand are decomposed, preferably in an oxygen containing environment, by heating or radiation with formation of the metal oxide.

A further aspect of this invention is directed to a precursor comprising at least one metal complex with a hydroxamato ligand, and that precursor can be decomposed to form a semiconductor, electronic component or a metal oxide.

Still another aspect of the invention is directed to a precursor composition comprising at least one metal complex with a hydroxamato ligand and a chalcogen source and that precursor composition can be decomposed to form a semiconductor.

### DETAILED DESCRIPTION

A general structure of a preferred hydroxamato ligand as referred to above and below is of the following formula (L):

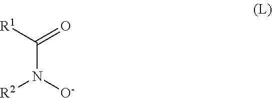

wherein R¹ is selected from C₁ to C₁₅ alkyl, phenyl or benzyl, preferably alkyl, more preferably C₁ to C₆ alkyl, and most preferably methyl, ethyl, iso-propyl or tert-butyl. R² is selected from H, C₁ to C₆ alkyls, preferably H, CH₃ or CH₂CH₃, and more preferably H. The hydroxamato ligand is a chelate ligand with one negative charge. As a chelate ligand it bonds to the metal via the two oxygen atoms. According to this invention the hydroxamate ligand is not to be confused with the neutral hydroxamic acids of formula LH, which also have some ligand properties.

The preferred mode for decomposition of the precursors is by heating, including baking, micro-waving, UV radiation and thermal radiation.

The term “chalcogen” according to this invention is limited to sulfur (S), selenium (Se) and to some degree tellurium (Te). Selenium (Se), sulfur (S) and combinations of S and Se are preferred chalcogens, whereas semiconductors comprising a certain Se content are especially preferred.

One, preferably two or all of the metal precursors of a precursor composition according to the invention comprise one or more hydroxamato ligand. In addition, one or more of the metals can be employed as known precursors, including e.g. acetylacetonates, acetates, oximates and other salts. The metal complexes are preferably metal hydroxamato complexes comprising the maximum number of hydroxamato ligands depending from their valence. A preferred zinc hydroxamate has e.g. the structure Zn(L)₂ with two hydroxamate ligands of the formula (L) described above. A complex of formula [Zn(L)(LH)]⁺ would be less preferable, since it requires an additional anion. Preferable the complexes have two, three or more hydroxamato ligands. Metals, which are preferably used with hydroxamato ligands, include aluminium, gallium, cadmium, copper, germanium, neodymium, ruthenium, magnesium, hafnium, indium, silver, tin, zirconium and zinc, preferably copper, indium, gallium, indium, zinc, aluminium, germanium, or tin.

The semiconductors containing chalcogenide and which are formed in the process according to the invention are preferably of the I-III-VI₂ or I-II/IV-VI₂ type. For the I-III-VI₂ type semiconductors one or more (+III) valency metals are used, preferably selected from In and Ga, more preferably In and In combined with Ga. The monovalent metal is preferably copper. The trivalent metals are preferably indium or gallium. Mixtures of these metals can be employed for tuning the band-gap of the semiconductor. Additionally, the tervalent metal can be exchanged partly or completely against a mixture of divalent and tetravalent metals (I-II/IV-VI₂-type semiconductor, e.g. Cu(Zn/Sn)Se₂, Cu(Zn/Ge)Se₂). Divalent metals are preferably cadmium or zinc, tetravalent metals are preferably germanium or tin.

The metal oxides formed in the process according to the invention are preferably copper oxide, indium oxide, gallium oxide, indium oxide, zinc oxide, aluminium oxide, germanium oxide, tin oxide and mixed metal oxides such as indium tin oxide, indium zinc oxide, gallium zinc oxide, indium gallium zinc oxide, aluminium zinc oxide etc. These metal oxides have various useful applications in electronics as conductors or semiconductors. The mechanism of thermal degradation involves the elimination of a volatile organoisonitrile molecule from each hydroxamato ligand in the coordination sphere of the respective precursor complex. Thereby, a clean conversion of the initial metal hydroxamato complex into the respective metal hydroxide intermediate is achieved, which subsequently undergoes a dehydration into the final metal oxide phase.

The precursors are preferably combined in a liquid phase, preferably a solvent providing good solubility of the components, and thus complete mixing of the metals with the optional chalcogen source is assured. The liquid phase preferably comprises an organic solvent or a mixture of two or more organic solvents. Usually the solvent evaporates quickly when the mixture is applied to a substrate and heated to at least above the boiling point of the solvents.

The precursor composition is preferably deposited on a substrate prior to decomposition, preferably by dip coating, spray coating, rod coating, spin coating, slit coating, drop casting, doctor blading, ink-jet printing or flexographic/gravure printing. Rapid evaporation and decomposition is preferred. In one preferred aspect of the invention the semiconductor or metal oxide is made by spray pyrolysis. The coating step is preferably repeated, intermitted or not by decomposition and/or heating of the material.

In the inventive process no oxides are produced unless it is desired. In case of the chalcogenides, the semiconductor materials consist of almost pure selenide/sulfide phases of the metals. In the presence of a source of chalcogen in the process, usually a pure chalcogenide phase is formed. Without the chalcogen source and in an oxygen containing environment the oxides are formed. Excessive heating of the chalcogenides in the presence of oxygen will usually also lead to oxides.

The level of impurities of the elements C/N/Cl is considerable lower than observed with methods according to prior art. The precursors are very stable in solution even at neutral conditions. This is a benefit over solutions made from metal chlorides and thiourea/selenourea which cause flocculation and have a considerable content of halogen. Alternatively an amount of acid or ethanolamine has to be added to stabilize those solutions. Furthermore, all of the current process steps can be performed under ambient pressure, which is a great economic benefit over previous vacuum deposition methods.

In a preferred embodiment, the precursor composition consists of a liquid phase containing the precursor materials. The liquid phase can easily be processed by transferring it to surfaces to be covered with semiconducting material by spraying, dropping, dipping, printing etc. The liquid phase may preferably comprise organic solvents and solvent mixtures, more preferably solvents in which the precursors are soluble, mostly preferred polar-aprotic solvents like dimethylformamide (DMF), dimethyl sulfoxide (DMSO), etc and protic solvents like methanol, ethanol, 2-methoxyethanol, isopropanol etc.

The thermal decomposition temperature of the precursor system according to the invention is as low as 150° C. and the end product after decomposition contains very low amounts of impurity elements like C or N (<1%).

The semiconductor layer typically has a thickness of 5 nm to 5 μm, preferably 30 nm to 2 μm. The layer thickness is dependent on the coating technique used in each case and the parameters thereof. In the case of spin coating, these are, for example, the speed and duration of rotation. In the case of spraying, the thickness can be increased with spraying time. In the case of rod coating and doctor blading the thickness can be increased by repeated deposition steps.

In accordance with the invention, the substrate can be either a rigid substrate, such as glass, ceramic, metal or a plastic substrate, or a flexible substrate, in particular plastic film or metal foil. In accordance with the invention, preference is given to the use of a substrate coated with molybdenum, which is very effective for the performance of solar cells.

The present invention furthermore relates to a process for the production of an electronic structure, preferably a device comprising a layered semiconductor or oxide, more preferably a photovoltaic device or photoconducting device, characterized in that
a) the precursor composition according to the invention is applied to a substrate in a layered manner, optionally one or more times, corresponding to the electronic structure to be achieved, preferably by dip coating, spray coating, rod coating, spin coating, slit coating, drop casting, doctor blading, ink-jet printing or flexographic/gravure printing,
b) drying and/or calcination of the applied precursor layer with formation of a semiconductor or oxide layer or surface, and
c) optionally supplying the applied electronic structure with additional layers and/or contacts.

Steps a) and b) can be performed concurrently by e.g. spraying on a hot substrate (spray pyrolysis). Repeating of step a) can be intermitted by one or more of steps b), which is preferred.

This process produces semiconducting or electronic components and optionally the connections of the components in a electronic structure. The electronic structure can be part of a photovoltaic device, wherein the absorber layer comprises the produced semiconductor. Certain metal oxides made easily accessible by the current invention are useful as transparent conductors or photoconductors.

Applying the precursor composition onto the substrate by processes such as dip coating, spray coating, rod coating, spin coating, slit coating, drop casting, doctor blading, ink-jet printing or flexographic/gravure printing is achieved analogous to methods familiar to the person skilled in the art (see M. A. Aegerter, M. Menning; Sol-Gel Technologies for Glass Producers and Users, Kluwer Academic Publishers, Dordrecht, Netherlands, 2004), where spray coating and doctor blading or printing is preferred in accordance with the invention.

In a preferred embodiment of the invention the absorber layer in a photovoltaic device is fabricated by depositing a precursor composition according to the invention, which is preferably solvent-based, onto a substrate and thermally decomposing the one or more precursors to obtain the semiconductor layer. For example a copper-selenium precursor and an indium precursor are co-deposited and heated in an inert or air environment afterwards in order to obtain a CIS layer.

Often, and in a preferred embodiment, two or more metals are used for the process, and the precursor composition comprises relative amounts of the metal precursors which are equivalent to the stoichiometry of the desired semiconductor. For a pure CIS layer equimolar amounts of copper and indium precursor would be employed. The copper and indium precursor ratios can also be adjusted to make either slightly copper poor or copper rich CIS layers. Slightly copper poor CIS compositions have been shown in literature to have better photovoltaic performance (S. Siebentritt et al., Solar Energy Materials & Solar Cells 2013, 119, 18-25).

In one embodiment of the current invention an additional compound comprising S, Se and/or Te and not comprising a metal is added into the process. It may be added at step a) by adding the compound to the combined precursors (the precursor composition) or during/after decomposition or heating. This optional source of S/Se/Te, which adds additional chalcogen, is preferably selected from organic compounds comprising selenium or sulphur or elemental selenium, sulphur or tellurium, more preferably from selenourea/thiourea or their derivatives by exchanging hydrogen with other organic groups, thioacetamide, or elemental S/Se/Te dissolved or suspended as a powder in amines (like hydrazine, ethylenediamine, ethanolamine etc.), phosphines (like tributylphosphine, trioctylphosphine, triphenylphosphine, etc.), organic solvents (like alcohols, DMF, DMSO etc.), solvent mixtures of the aforementioned, or other suitable liquid carriers. Sulfur and selenium are preferred chalcogens in this connection.

The precursor composition for chalcogenide formation comprises at least an amount of the chalcogen components relative to the amount of metal which is equivalent to the stoichiometry of the desired semiconductor or more. Optionally an excess amount of the chalcogen can be used, because some of the selenium or sulfur may be lost due to the chalcogen volatility during annealing and decomposing the precursor composition. The amount of chalcogen is preferably 100% (stoichiometric, 0% excess) to 400% (300%) excess) relative to the theoretical metal content, more preferably 10-150° A) excess.

In another embodiment of the invention stoichiometric amounts of sulfur and additional selenium is included in the precursor comprising the first metal.

The precursor composition can be deposited on a “hot” substrate to decompose the precursor in-situ to form a semiconductor layer. This method, practiced as spray pyrolysis, prevents crystallization of single species from the mixture prior to decomposition while the liquid carrier evaporates. The produced materials or layers may have a more homogeneous spatial distribution of the elements, but some additional surface roughness may be caused by spray deposition.

Another method to produce the semiconductor or oxide material or the absorber layer is to deposit the precursor solution onto a substrate held at a temperature below the temperature of decomposition, typically at room temperature. This step is followed by annealing the films preferably in inert environment at the decomposition temperature of the precursors to convert the precursor films into a semiconductor layer, e.g. a CIS layer. An intermediate step can be the evaporation of the liquid carrier. This method provides more time to evenly distribute the precursor composition in the required form or thickness onto a substrate.

In a third embodiment of the method the precursor composition is spray dried into hot inert gas providing a fine powder or grains of the semiconductor.

The thermal conversion of the metal complex precursor into the functional semiconductor layer is carried out at a temperature ≧150° C., preferably ≧200° C. and more preferably ≧300° C. The temperature is preferably between 150 and 400° C. Oxides made by one of the inventive processes may be annealed to even higher temperatures. While only moderate temperatures are necessary to convert the precursors, further annealing of the films at certain temperatures can be made in order to obtain certain crystal phases or morphologies having the desired properties. The residue after decomposition does not contain any significant carbon contamination (<1%).

In case of the semiconductors, the first decomposition step can be followed by further annealing steps to improve the electronic properties and crystallinity and/or grain size of the semiconductor, preferably the layer of semiconductor (more preferably CIS or CIGS layer). The grain size of the semiconductor film can be increased by increasing the annealing temperature and annealing time. No intermediate phases (which are detrimental to the PV performance) are formed if the precursors are completely decomposed. Principally no additional high temperature selenization or sulfurization step above 250° C. (i.e annealing the films in chalcogen vapour) is required for the formation of the semiconductor film. Therefore in one preferred embodiment of the invention the process for the manufacture of a photovoltaic device according to the invention is free of any additional selenization and/or sulfurization step at temperatures above 250° C. This way the temperatures in a process can be kept at 200° C. or lower.

On the other hand, annealing and selenization may still provide improved device performance due to other effects than precursor decomposition. Grain size and grain boundaries can be optimized at high temperatures, while extra chalcogen (usually Se or S) is optionally supplied in the gas phase at these temperatures in order to keep its contents stable. Other than elemental chalcogen vapors hydrogen sulfide (H₂S) or hydrogen selenide (H₂Se) gases may also be used for selenization or sulfurization. Therefore, in another preferred embodiment of the invention the inventive process according to the invention includes as a further step a selenization and/or sulfurization step and/or an annealing step after the decomposition of the precursors. The amount of chalcogen in the annealed films can be controlled by the initial chalcogen content in the precursor solution, by the amount and type of chalcogen present in the vapor phase and by the annealing/decomposition temperature and time.

The conversion of the metal complex precursor or the precursor composition into the functional semiconductor layer is carried out in a further preferred embodiment by irradiation, preferably electromagnetic irradiation, including microwaves, IR, and UV, with preference to UV light at wavelengths <400 nm. The wavelength is preferably between 150 and 380 nm. The advantage of UV irradiation is that the layers produced thereby have lower surface roughness.

The electronic component is provided with contacts to the semiconductor or metal oxide and completed in a conventional manner. For photovoltaic devices a transparent top electrode made from e.g. ZnO or indium-tin oxide and a metal grid is provided.

Conventional means may be employed to optimize the photovoltaic device performance. Selenization/sulfurization (see above), treatment with aqueous cyanide to remove traces of copper selenide or copper sulfide, a thioacetamide/InCl₃ wash for band gap optimization and application of various contact layers (CdS, ZnO, ITO) may be employed to the semiconducting layer.

The present invention furthermore relates to the use of the metal complex or precursor composition according to the invention for the production of one or more functional layers, preferably the absorber layer, in a photovoltaic device.

The precursors or complexes are formed at room temperature by reaction of a hydroxamic acid with at least one metal salt, such as, for example, nitrates, chlorides, oxichlorides, etc. in the presence of a base, such as, for example, ammonia, tetraethylammonium hydrogencarbonate or sodium hydrogencarbonate. Especially suitable hydroxamic acids are lower alkyl derivatives (C₁-C₆), wherein the alkyl group can be branched or linear. Hydroxamic acids can be prepared in a known manner from the reaction of carbonic acid chlorides with hydroxylamine or N-alkylhydroxylamines or their respective salts.

The following abbreviations are used above and below:

PCE power conversion efficiency,
FF fill factor,
V_{oc} open circuit voltage,
J_{sc} short circuit current density,
DMF N,N-dimethylformamide, a solvent.

The following examples are intended to illustrate the present invention. However, they should in no way be regarded as limiting.

### Preparation of the Metal Precursors:

Below some examples of precursors are listed where metal is complexed with hydroxamato ligands. The complexes were prepared as described below.

### EXAMPLES

### Preparation of Pivalohydroxamato Metal Complexes

### Example 1

### Pivalohydroxamic Acid, t-BuCONHOH

Hydroxylamine hydrochloride (12 g, 173 mmol) and potassium carbonate (23.9 g, 173 mmol) were dispersed in a mixture of ethyl acetate (100 ml) and water (1 ml), and pivaloyl chloride (20.86 g, 173 mmol) was added dropwise under stirring at 0-5° C. The mixture as allowed to warm to ambient temperature under continuous stirring for 1 h. The resulting slurry was heated to reflux, and the solid was removed by hot filtration and washed with 3×100 ml of boiling ethyl acetate. The combined filtrates were dried over MgSO₄ filtered again, concentrated to 100 ml, and stored at −20° C. for 12 h. The precipitated white needles were collected by filtration, washed with ether (20 ml) and dried in vacuo.

Pivalohydroxamic acid. From pivaloyl chloride (20.86 g, 173 mmol). Yield: 15.8 g (78%). Mp: 161° C. (Lit: 161° C. Berndt, D. C et al. Org. Chem. 1964, 29, 916).

Isobutyrohydroxamic acid. From isobutyryl chloride (18.43 g, 173 mmol). Yield: 14.30 g (80%). Mp: 117° C. (Lit: 116° C. Ando, W. et al. Synth. Comm. 1983, 13, 1053).

### Example 2

Tris(O,O-pivalohydroxamato)iron, (t-BuCONHO)₃Fe, and Bis(O,O-pivalohydroxa-mato)copper, (t-BuCONHO)₂Cu, were prepared by published procedures. (Leigh, T. et al. British Patent 894,120, 1960).

Some of the following complexes that are described in this disclosure below are unprecedented and not reported in literature.

### Example 3

### Tris(O,O-pivalohydroxamato)aluminium, (t-BuCONHO)₃Al

Aluminium isopropoxide (1.021 g, 5 mmol) was dissolved under stirring in a hot solution of pivalohydroxamic acid (1.757 g, 15 mmol) in dry ethanol (30 ml), and the mixture was heated under reflux for 15 min. A white precipitate formed upon cooling, which was collected by filtration after stirring at ambient temperature for 2 h. Washing with 5 ml of ethanol and 2×10 ml of ether afforded 1.48 g (3.94 mmol, 79%) of white powder after drying in vacuo. Elemental analysis calc. (found) for C₁₅H₃₀AlN₃O₆ (M=375.40 g mol⁻¹): C, 47.99 (47.63); H, 8.05 (8.01); N, 11.19 (11.13) %. ¹H-NMR (500 MHz, CD₃OD), δ=1.09 (s, 9H, t-Bu), 4.74 (s, 1H, NH) ppm. ¹³C-NMR (125 MHz, CD₃OD), δ=27.02 (CH₃), 35.96 (C(CH₃)₃), 174.08 (C═O) ppm. IR (ATR), 1617 (v_{C═O}); 1523 (v_{C—N}); 1223 (v_{N—O}) cm⁻¹.

### Example 4

### Tris(O,O-pivalohydroxamato)gallium, (t-BuCONHO)₃Ga

GaCl₃ (1.439 g, 8.17 mmol) was dissolved in 20 ml of water, and 17 ml of a 1 molar solution of ammonia was added under stirring. A solution of pivalohydroxamic acid (2.9 g, 24.8 mmol) in ethanol (60 ml) was added to this mixture, followed by another 7.8 ml of 1 molar ammonia solution. All volatiles were removed under vacuum after stirring the mixture for 20 h at room temperature, and the remainder was extracted with a mixture of 400 ml of CH₂Cl₂ and 100 ml of ethanol. The extract was cleared from precipitated NH₄Cl by-product by filtration and evaporated to dryness again. The as-obtained white powder was dissolved in 30 ml of hot ethanol, and 100 ml of water was added. The resulting mixture was concentrated in vacuo on a rotary evaporator until the onset of precipitation. After standing overnight, the precipitated product was collected by filtration, washed with water (3×20 ml) and acetone (5 ml) and dried in vacuo. Yield: 1.88 g (55%). Elemental analysis calc. (found) for C₁₅H₃₀GaN₃O₆ (M=418.14 g mol⁻¹): C, 43.08 (43.08); H, 7.23 (7.14); N, 9.99 (10.00) %. ¹H-NMR (500 MHz, CD₃OD), δ=1.10 (s, 9H, t-Bu), 4.70 (s, 1H, NH) ppm. ¹³C-NMR (125 MHz, CD₃OD), δ=27.16 (CH₃), 36.73 (C(CH₃)₃), 173.76 (C═O) ppm. IR (ATR), 1597 (v_{C═O}); 1533 (v_{C—N}); 1220 (v_{N—O}) cm⁻¹.

### Example 5

### Tris(O,O-pivalohydroxamato)indium, (t-BuCONHO)₃In

25 ml of a 1 molar solution of ammonia was added to a stirred suspension of pivalohydroxamic acid (2.9 g, 24.8 mmol) in water (30 ml), resulting in complete dissolution. A solution of In(NO₃)₃×6 H₂O (2.5 g, 6.1 mmol) in 20 ml water was added dropwise. A white precipitate formed gradually. The mixture was stirred at room temperature for 20 h, and the white product was collected on a filter, washed with 3×20 ml of water and 3×2 ml of acetone, and dried in vacuo. Yield 2.753 g (5.95 mmol, 97%). Elemental analysis calc. (found) for C₁₅H₃₀InN₃O₆ (M=463.24 g mol⁻¹): C, 38.89 (39.15); H, 6.53 (6.52); N, 9.07 (8.98) %. ¹H-NMR (500 MHz, CD₃OD), δ=1.01 (s, 9H, t-Bu), 4.70 (s, 1H, NH) ppm. ¹³C-NMR (125 MHz, CD₃OD), δ=27.25 (CH₃)₃, 37.76 (C(CH₃)₃), 174.32 (C═O) ppm. IR (ATR), 1589 (v_{C═O}); 1520 (v_{C—N}); 1220 (v_{N—O}) cm⁻¹.

### Example 6

### Bis(O,O-pivalohydroxamato)zinc hemiethanolate, (t-BuCONHO)₂Zn×0.5 EtOH

A solution of pivalohydroxamic acid (0.55 g, 4.7 mmol) in ethanol (10 ml) and water (10 ml) was added to a stirred solution of zinc acetate dihydrate (0.5 g, 2.28 mmol) in 10 ml of water. A voluminous white precipitate started to form after 2 min. After stirring for 2 h, the precipitate was collected by filtration, washed subsequently with 5 ml of water and 2×5 ml of acetone, and dried in vacuo. Yield: 0.44 g (1.37 mmol, 60%). Elemental analysis calc. (found) for C₁₀H₂₀N₂O₄Zn×0.5 C₂H₆O (M=320.69 g mol⁻¹): C, 41.20 (41.28); H, 7.23 (7.10); N, 8.74 (8.68) %. ¹H-NMR (500 MHz, DMSO-d⁶), δ=1.10 (s, 9H, t-Bu), 10.86 (s, 1H, NH) ppm. ¹³C-NMR (125 MHz, DMSO-d⁶), δ=27.47 (CH₃), 35.67 (C(CH₃)₃), 171.04 (C═O) ppm. IR (ATR), 1580 (v_{C═O);} 1504 (v_{C—N}); 1218 (v_{N—O}) cm⁻¹.

### Example 7

### Bis(O,O-pivalohydroxamato)tin, (t-BuCONHO)₂Sn

Solid stannous methoxide (Sn(OCH₃)₂, 1.56 g, 8.63 mmol) was dissolved in a solution of pivalohydroxamic acid (2.068 g, 17.65 mmol) in dry ethanol (40 ml) at 50° C. The clear solution was stirred at ambient temperature for 3 h. The volume of the solution was reduced in vacuo to 20 ml, and 40 ml of ether was added. Storage at −20° C. overnight afforded fine white needles, which were isolated by filtration, washed twice with 10 ml of ether and dryed in vacuo. Yield 2.03 g (5.78 mmol, 67%). Elemental analysis calc. (found) for C₁₀H₂₀N₂O₄Sn (M=350.99 g mol⁻¹): C, 34.22 (34.35); H, 5.74 (5.63); N, 7.98 (8.02) %. ¹H-NMR (500 MHz, CD₃OD), δ=1.21 (s, 9H, t-Bu), 4.86 (s, 1H, NH) ppm. ¹³C-NMR (125 MHz, CD₃OD), δ=27.62 (CH₃), 36.82 (C(CH₃)₃), 173.86 (C═O) ppm. IR (ATR), 1572 (v_{C═O);} 1516 (v_{C—N}); 1224 (v_{N—O}) cm⁻¹.

### Example 8

### Tris(O,O-isobutyrohydroxamato)aluminium, (i-PrCONHO)₃Al

Aluminium isopropoxide (1.021 g, 5 mmol) was added under stirring to a hot solution of isobutyrohydroxamic acid (1.547 g, 15 mmol) in dry ethanol (30 ml), and the mixture was heated under reflux for 15 min. The product precipitated partially as a fine white powder already during the dissolution of the aluminium isopropoxide. More product formed upon cooling, which was collected by filtration after stirring at ambient temperature for 5 h. Washing with 5 ml of ethanol and 2×10 ml of ether afforded 1.545 g (4.64 mmol, 92%) of white powder after drying in vacuo. Elemental analysis calc. (found) for C₁₂H₂₄AlN₃O₆ (M=333.28 g mol⁻¹): C, 43.25 (43.07); H, 7.26 (7.42); N, 12.61 (11.97) %. ¹H-NMR (500 MHz, CD₃OD), δ=1.19 (d, ³J=6.8 Hz, 6H, CH₃), 2.51 (sept, ³J=7.0 Hz, 1H, CH), 4.82 (s, 1H, NH) ppm. ¹³C-NMR (125 MHz, CD₃OD), δ=19.26 (CH₃), 30.99 (CH), 172.44 (C═O) ppm. IR (ATR), 1611 (v_{C═O}); 1552 (v_{C—N}); 1294 (v_{N—O}) cm⁻¹.

### Example 9

### Tris(O,O-isobutyrohydroxamato)gallium hemiethanolate, (i-PrCONHO)₃Ga×0.5 EtOH

A solution of isobutyrohydroxamic acid (1.072 g, 10.43 mmol) in 1 n NH₃ (10.5 ml) was added to gallium sulphate hydrate (1.227 g, 3.46 mmol) in 20 ml water, and the mixture was stirred for 1 h before all volatiles were removed by rotary evacuation. The residue was extracted with 100 ml of hot ethanol. The extract was cleared by filtration through a 1 cm layer of celite and evaporated to dryness. The residue was suspended in 10 ml of cold ethanol, collected by filtration, washed with ether, and dried in vacuo. Yield 1.01 g (2.53 mmol, 73%). Elemental analysis calc. (found) for C₁₂H₂₄GaN₃O₆×0.5 C₂H₆O (M=399.09 g mol⁻¹): C, 39.13 (39.16); H, 6.82 (6.76); N, 10.53 (10.67) %. ¹H-NMR (500 MHz, CD₃OD), δ=1.19 (d, ³J=7.0 Hz, 6H, CH₃), 2.52 (sept, ³J=7.0 Hz, 1H, CH), 4.82 (s, 1H, NH) ppm. ¹³C-NMR (125 MHz, CD₃OD), δ=19.37 (CH₃), 31.83 (CH), 171.96 (C═O) ppm. IR (ATR), 1600 (v_{C═O}); 1548 (v_{C—N}); 1287 (v_{N—O}) cm⁻¹.

### Example 10

### Tris(O,O-isobutyrohydroxamato)indium, (i-PrCONHO)₃In

20 ml of 1 n NH₃ was added to a stirred solution of In(NO₃)₃×H₂O (1 g, 3.12 mmol) in 20 ml water, and the precipitated In(OH)₃ was collected by centrifugation and washed three times by slurrying in water (40 ml) and subsequent centrifugation. The moist powder was dissolved in a solution of isobutyrohydroxamic acid (1.023 g, 9.9 mmol) in methanol (20 ml) under stirring within 10 min. The resulting solution was filtered and concentrated to dryness in vacuo. The residue was stirred in ethanol (5 ml) for 10 min and the insoluble white powder was collected on a filter, washed with ether (20 ml), and dried in vacuo. Yield 1.709 g (4.06 mmol, 65%). Elemental analysis calc. (found) for C₁₂H₂₄InN₃O₆ (M=421.16 g mol⁻¹): C, 34.22 (34.17); H, 5.74 (5.70); N, 9.98 (9.88) %. ¹H-NMR (500 MHz, CD₃OD), δ=1.18 (d, ³J=7.0 Hz, 6H, CH₃), 2.50 (sept, ³J=7.0 Hz, 1H, CH), 4.82 (s, 1H, NH) ppm. ¹³C-NMR (125 MHz, CD₃OD), δ=19.52 (CH₃), 32.98 (CH), 172.66 (C═O) ppm. IR (ATR), 1588 (v_{C═O);} 1527 (v_{C—N}); 1291 (v_{N—O}) cm⁻¹.

### Example 11

### Bis(O,O-isobutyrohydroxamato)tin, (i-PrCONHO)₂Sn

Solid stannous methoxide (1 g, 5.52 mmol) was added in portions to a solution of isobutyrohydroxamic acid (1.14 g, 11.1 mmol) in dry ethanol (40 ml), and the mixture was stirred at 40° C. until dissolution was completed. White needles formed within 24 h at −20° C. after concentration to 20 ml in vacuo and dilution with an equal volume of ether. Filtration, washing with 2×10 ml of ether and drying in vacuo afforded 1.064 g (3.30 mmol, 60%). Elemental analysis calc. (found) for C₈H₁₆N₂O₄Sn (M=322.94 g mol⁻¹): C, 29.75 (29.89); H, 4.99 (4.99); N, 8.67 (8.86) %. ¹H-NMR (500 MHz, CD₃OD), δ=1.17 (d, ³J=7.0 Hz, 6H, CH₃), 2.59 (sept, ³J=7.0 Hz, 1H, CH), 4.84 (s, 1H, NH) ppm. ¹³C-NMR (125 MHz, CD₃OD), δ=19.74 (CH₃), 31.39 (CH), 172.26 (C═O) ppm. IR (ATR), 1589 (v_{C═O);} 1529 (v_{C—N}); 1266 (v_{N—O}) cm⁻¹.

### Example 12

### Bis(O,O-isobutyrohydroxamato)zinc, (i-PrCONHO)₂Zn

A solution of zinc sulfate heptahydrate (2.5 g, 8.69 mmol) in water (10 ml) was added to a stirred solution of isobutyrohydroxamic acid (1.81 g, 17.56 mmol) in 1 n NH₃ (18 ml). A voluminous white precipitate deposited within 2 h, which was collected by filtration, washed with 2×10 ml of water and 5 ml of acetone, and dried in vacuo. Yield: 1.704 g (6.32 mmol, 73%). Elemental analysis calc. (found) for C₈H₁₆N₂O₄Zn (M=269.62 g mol⁻¹): C, 35.64 (35.58); H, 5.98 (5.95); N, 10.39 (10.19) %. ¹H-NMR (500 MHz, DMSO-d⁶), δ=1.02 (d, ³J=7.0 Hz, 6H, CH₃), 2.28 (sept, ³J=7.0 Hz, 1H, CH), 4.35 (s, 1H, NH) ppm. ¹³C-NMR (125 MHz, DMSO-d⁶), δ=20.05 (CH₃), 32.66 (CH), 173.54 (C═O) ppm. IR (ATR), 1605 (v_{C═O}); 1525 (v_{C—N}); 1261 (v_{N—O}) cm⁻¹.

### Preparation of N-Methylacetohydroxamato Metal Complexes

### Example 13

### N-Methylacetohydroxamic Acid, CH₃CON(CH₃)OH

Triethylamine (66 ml, 47.92 g, 474 mmol) was added dropwise to a stirred solution of N-methylhydroxylamine hydrochloride (15.87 g, 190 mmol) in methanol (100 ml) at 0-5° C. After stirring for 30 min, acetyl chloride (17.27 g, 15.6 ml, 220 mmol) was slowly added dropwise, and the resulting slurry was allowed to warm to ambient temperature under stirring. 500 ml of ether was added, and the precipitated triethylammonium chloride was removed by filtration and washed with ether (3×100 ml). The combined filtrate and ether washings were concentrated in vacuo on a rotary evaporator. The oily residue was distilled under reduced pressure. Bp: 68-73° C. (2 mbar). Yield: 11.89 g (70%).

### Example 14

### Tris(N-methylacetohydroxamato)gallium, (CH₃CON(CH₃)O)₃Ga

(Bradley, F. C et al. European Patent 0 502 709 A1, 1992.)

A 1 molar solution of ammonia (45 ml) was added to a stirred solution of gallium nitrate monohydrate (4.106 g, 15 mmol) in water (50 ml). N-Methylacetohydoxamic acid (4.01 g, 45 mmol) was added dropwise to the resulting gallium hydroxide slurry, and the mixture was stirred overnight. The solution was filtered, and the filtrate was evaporated to dryness on a rotary evaporator. The residue was dissolved in 100 ml of hot ethanol, and the filtered extract was concentrated until precipitation started. Storage at −20° C. overnight, filtration of the precipitate, washing with ether (5 ml), and drying under vacuum afforded 4.02 g (80%) of light orange crystals. The product was recrystallized from a concentrated solution in dichloromethane by layering with ether. Elemental analysis of the as-prepared crystals revealed the incorporation of 1 equivalent of dichloromethane. Elemental analysis calc. (found) for C₉H₁₈GaN₃O₆×CH₂Cl₂ (M=418.92 g mol⁻¹): C, 28.67 (28.31); H, 4.81 (4.84); N, 10.03 (10.24) %. ¹H-NMR (500 MHz, CDCl₃), δ=2.15 (s, 3H, CH₃—C); 3.56 (s, 3H, CH₃—N); 5.34 (s, 1H, CH₂Cl₂) ppm. ¹³C-NMR (125 MHz, CDCl₃), δ=17.33 (CH₃—C); 38.89 (CH₃—N); 53.43 (CH₂Cl₂); 161.02 (C═O) Ppm. IR (ATR), 1605 (v_{C═O}); 1425 (v_{C—N}); 1173 (v_{N—O}) cm⁻¹.

### Example 15

### Tris(N-methylacetohydroxamato)indium, (CH₃CON(CH₃)O)₃In

60 ml of a 1 molar solution of ammonia was added to a stirred solution of InCl₃×2 H₂O (5.16 g, 20 mmol) in water (65 ml). N-methylacetohydroxamic acid (8.44 g, 94 mmol) was added dropwise to the resulting suspension. The mixture was stirred at room temperature for 2 h, and subsequently all volatiles were removed on a rotary evaporator. The residue was extracted with dichloromethane (100 ml), and the insolubles were removed by filtration through a 1 cm layer of celite and washed with dichloromethane (50 ml). The combined filtrates were evaporated to dryness, and the oily residue was re-dissolved in 10 ml of dichloromethane. Addition of ether (50 ml) and storage at −20° C. overnight afforded 6.01 g (15.85 mmol, 79%) of colourless crystals after filtration, washing with ether and drying in vacuo. Elemental analysis calc. (found) for C₉H₁₈InN₃O₆ (M=379.09 g mol⁻¹): C, 28.52 (28.59); H, 4.79 (4.78); N, 11.08 (10.98) %. ¹H-NMR (500 MHz, CDCl₃), δ=2.16 (s, 3H, CH₃—C); 3.45 (s, 3H, CH₃—N) ppm. ¹³C-NMR (125 MHz, CDCl₃), δ=18.67 (CH₃—C); 40.01 (CH₃—N); 161.95 (C═O) ppm. IR (ATR), 1592 (v_{C═O}); 1422 (v_{C—N}); 1162 (V_{N—O}) cm⁻¹.

### Example 16

### Bis(N-methyl-acetohydroxamato)zinc, (CH₃CON(CH₃)O)₂Zn

A solution of ZnSO₄×7 H₂O (2.87 g, 10 mmol) in water (20 ml) was added dropwise to a stirred solution of N-methylacetohydroxamic acid (1.90 g, 21.3 mmol) in 1 n NH₃ (22 ml). The mixture was evaporated to dryness in vacuo after stirring at room temperature for 6 h. The residue was extracted with dichloromethane (2×50 ml), and the filtered extract was concentrated to a volume of 10 ml, layered with ether (50 ml) and stored at −20° C. for 1 h. 1.214 g (5.03 mmol, 50%) of light yellow crystals were obtained after filtration, washing with ether and drying in vacuo. Elemental analysis calc. (found) for C₆H₁₂N₂O₄Zn (M=241.57 g mol⁻¹): C, 29.83 (30.02); H, 5.01 (5.01); N, 11.60 (11.41) %. ¹H-NMR (500 MHz, CDCl₃), δ=2.08 (s, 3H, CH₃—C); 3.42 (s, 3H, CH₃—N) ppm. ¹³C-NMR (125 MHz, CDCl₃), δ=18.56 (CH₃—C); 39.59 (CH₃—N); 162.98 (C═O) ppm. IR (ATR), 1594 (v_{C═O}); 1425 (v_{C—N}); 1161 (v_{N—O}) cm⁻¹.

### Example 17

### TGA Analysis

Thermogravimetric analysis (TGA) measurements were carried out with a TG-209-F1 (Netzsch) at a heating rate of 10 K/min in aluminium crucibles under helium atmosphere. The resulting TGA traces are displayed in FIG. 1, while relevant data are summarized in Table 1.

TABLE 1
Thermogravimetric analysis data of various
metal hydroxamato complexes.

| | Product | Ceramic | Ceramic | | |
|---|---|---|---|---|---|
| Precursor | phase | yield | yield | Onset of | End of |
| complex | [ICSD | (calc.) | (found) | decomp. | decomp. |
| (Example no.) | code] | [%] | [%] | [° C.] | [° C.] |
| In(III)iBuH*H₂O | In₂O₃ | 32.96 | 33.20 | 150 | 380 |
| (10) | [14387] | | | | |
| Ga(III)iBuH | Ga₂O₃ | 24.92 | 27.44 | 120 | 600 |
| (9) | [34243] | | | | |
| Al(III)iBuH | γ-Al₂O₃^{a)} | 15.30 | 16.40 | 230 | 500 |
| (8) | [28260] | | | | |
| Zn(II)iBuH | ZnO | 33.69 | 32.97 | 160 | 374 |
| (12) | (Zincite) | | 31.10 | | 578 |
| | [57450] | | | | |
| Sn(II)iBuH | SnO₂ | 46.67 | 45.33 | 140 | 475 |
| (11) | (Cassit- | | | | |
| | erite) | | | | |
| | [9163] | | | | |
| In(III)PvH | In₂O₃ | 29.97 | 31.01 | 210 | 334 |
| (5) | [14387] | | | | |
| Ga(III)PvH | Ga₂O₃ | 22.41 | 29.65 | 210 | 410 |
| (4) | [34243] | | | | |
| Al(III)PvH | γ-Al₂O₃^{a)} | 15.30 | 15.28 | 198 | 420 |
| (3) | [28260] | | | | |
| Zn(II)PvH | ZnO | 25.79 | 25.64 | 72 | 576 |
| (6) | (Zincite) | | | | |
| | [57450] | | | | |
| Sn(II)PvH | SnO₂ | 42.94 | 41.5 | 140 | 330 |
| (7) | (Cassit- | | | | |
| | erite) | | | | |
| | [9163] | | | | |
| Fe(III)PvH* | Fe₃O₃ | | 92.21 | 76 | 150 |
| EtOH | (Hematite) | 17.57 | 16.20 | 150 | 400 |
| (2) | [24791] | | | | |
| Cu(II)PvH | CuO | 26.89 | 26.50 | 182 | 250 |
| (2) | (Tenorite) | | 24.90 | 250 | 370 |
| | [16025] | | | | |
| Ga(III)MeAcH | Ga₂O₃ | 28.06 | 20.51 | 236 | 600 |
| (14) | [34243] | | | | |
| In(III)MeAcH | In₂O₃ | 36.62 | 29.15 | 210 | 590 |
| (15) | [14387] | | | | |
| Zn(II)MeAcH | ZnO | 33.69 | 35.38 | 160 | 600 |
| (16) | (Zincite) | | | | |
| | [57450] | | | | |

Abbrevations: iBuH: O,O-isobutyrohydroxamato, PvH: O,O-pivalohydroxamato, MeAcH: N-methylacetohydroxamato.
^{a)}Conversion into α-Al₂O₃ [9770] at T > 800° C.
^{a)}Conversion into α-Al₂O₃ [9770] at T > 800° C.

The thermal degradation of all isobutyro- and pivalohydroxamato metal complexes, with the exception of the respective Zn(II) derivatives, is virtually complete at temperatures below 400° C., while the onset of the degradation process lies in a temperature range between 140 and 290° C. Minor mass loss steps at temperatures below 140° C., which were observed in some cases, may be ascribed to the loss of solvate molecules. Two distinct mass loss steps can be observed in the TG traces of In(III)-isobutyrohydroxamate and both N-unsubstituted Zn(II)-hydroxamato derivatives, while the separation of these degradation steps is less pronounced or even undetectable in the remaining examples. Monitoring of the degradation for those examples with a well separated two-step TG trace by means of TG-MS and TG-IR revealed that the first major mass loss step is accompanied by a release of isopropyl and tert-butyl isocyanate for isobutyrohydroxamato and pivalohydroxamato metal complexes, respectively. These findings support the assumption that metal hydroxamato complexes decompose via a metal-assisted Lossen rearrangement pathway, as proposed recently for the decomposition of Zn(II)hydroxamato complexes in solution. (Ja\check{s}iková, L. et al. J. Org. Chem. 2012, 77, 2829). The extrusion of an organoisocyanate from a hydroxamato ligand in course of the proposed decomposition process leaves a hydroxo ligand on the metal center. The resulting metal hydroxides will then convert under subsequent condensation into the finally obtained metal oxide phase. The proposed Lossen rearrangement mechanism may also account for the fact that pure metal oxide phases are isolated even if the decomposition is carried out in an inert atmosphere. The ceramic yields obtained in almost all studied degradation experiments under helium atmosphere approach the expected values for the respective metal oxide phases which were detected by X-ray diffractometry if the annealing was carried out in air (vide infra). However, the deviation from the expected ceramic yield that was obtained in the degradation of both the pivalo- and isobutyrohydroxamato complexes of Ga(III) does not indicate the Lossen rearrangement mechanism applies here.

Further evidence for the assumption of a Lossen-type decomposition mechanism is derived from the different thermal degradation behaviour that is exhibited by the investigated N-methyl-acetohydroxamato metal complexes. The TG traces of the respective derivatives are presented in FIG. 1c. Though most of the mass decrease takes place in only one major step at temperatures well below 350° C. in all investigated examples, there are still distinct mass losses observed at temperatures up to 600° C. Moreover, the ceramic yield of the Ga and In derivatives at 600° C. falls below the respective theoretic value distinctly, thereby indicating major mass losses due to sublimation of intact molecules, which in turn points to an increased volatility and thermal robustness of the respective precursor complexes. This deviating behavior of the N-methyl-acetohydroxamato metal complexes may be ascribed to the fact that the presence of the methyl substituent on the N atom in this ligand will prevent the necessary tautomerization step, which is a prerequisite for the Lossen rearrangement mechanism, while the increased volatility may derive from the absence of a NH function on the amide moiety of the hydroxamato ligand. The missing NH function renders the respective N-methyl-acetohydroxamato metal complexes unable to form intermolecular hydrogen bond networks in the crystalline state.

### Example 18

### Preparative Thermal Degradation in Air

400 mg samples of the respective pivalo- and isobutyrohydroxamato metal complexes in ceramic crucibles were placed in a furnace and heated in air at 400° C. for 4 h, then allowed to cool to ambient temperature. Subsequently the samples were heated at 600° C., 800° C., and if required 1000° C. for 2 h, respectively. The heating up time was 2 h in all cases. Samples for XRD analysis were taken after each heating cycle. The resulting diffractograms are presented in FIGS. 2 and 3 in combination with the simulated line diffractogram of the respective product phase.

### Example 19

### Preparation of ITO Films from Hydroxamato Metal Precursors

A stock solution of 5 wt % precursor complex concentration with In/Sn ratio of 9:1 was prepared by dissolving tris(O,O-isobutyrohydroxamato)indium (117 mg, 0.278 mmol) and bis(O,O-isobutyrohydroxamato)tin (10 mg, 0.031 mmol) in 2.64 ml 2-methoxyethanol under moderate warming. The solution was filtered through a 0.2 μm PTFE syringe filter after cooling to ambient temperature directly before use. Silicon wafer and alkaline-free glass substrates (15×15 mm), as well as quartz substrates (10×10 mm), were cleaned by subsequent washing with acetone and isopropanol in an ultrasonicator, followed by air-plasma treatment for 1 min. ITO films were prepared by spin-coating of the stock solution onto the respective substrate (1000 rpm for 6 s, 2500 rpm for 20 s), followed by thermal decomposition on a hotplate in ambient air for 5 min at 400 or 450° C., respectively, and subsequent cooling in an argon stream for 10 s. A ten-fold repetition of the spin-coating procedure afforded ITO films with a thickness of 142 and 139 nm for samples processed at 400 and 450° C., respectively, as determined by white light interferometry using a NewView 6200 (Zygo). Scanning electron microscopy (SEM) micrographs were taken using a XL 30FEG (Philips) operated at 20 kV. A SEM micrograph of a five layer ITO film sample on a silicon wafer support (not shown herein) revealed that the film was quite uniform and smooth. The thermal degradation did not give rise to the formation of cracks. The high conductivity of the as-prepared film allowed for a direct SEM analysis without the requirement of depositing a Au layer onto the surface. A XRD study of ITO thin films on alkaline-free glass substrates measured in reflexion on a STOE & CIE STADIP diffractometer revealed that the product crystallized in the cubic In₂O₃ phase [ICSD 88 2160]. Diffractograms of ITO thin films on alkaline-free glas supports processed at 400 and 450° C., respectively, are presented in FIG. 4. Rietveld analysis of the diffractograms afforded a lattice constant of a=10.100 Å for both samples, which is in good agreement with reported data (Quaas, M. et al. Thin Solid Films 1998, 332, 277). XPS analysis of the as-prepared samples on silicon wafer substrates indicated a In/Sn atomic ratio of 7.69 and 8.03 for samples processed at 400 and 450° C., respectively. Therefore, the final composition of the product coincided reasonably well with the initial molar ratios of the two precursor complexes used in the syntheses. Electrical characterization was carried out with an HP 4155A Semiconductor Parameter Analyzer (Agilent). The electrical resistivity of ITO thin films on alkaline-free glass substrates amounted to 0.131 and 0.125 Ωcm for samples processed at 400 and 450° C., respectively, as determined by four point measurement. These values are in good agreement with reported electrical resistivities of ITO thin films that were prepared by other solution-based deposition methods (Hoffmann, R. C. et al. J. Phys. Status Solidi A, 2011, 208, 2920).

### Example 20

### A Photovoltaic CIGS Device Made from Spray Coating an Ink Based on Hydroxamato Precursors

A CIGS precursor ink was made by dissolving Tris(N-methylaceto-hydroxamato)gallium (CH₃CON(CH₃)O)₃Ga (0.375 mmol), Tris(N-methylacetohydroxamato)indium (CH₃CON(CH₃)O)₃In (0.7 mmol), Diaquabis(2-hydroxyiminopropionato)copper (0.95 mmol) (copper precursor prepared similar to literature M. Aymaretto, Gazzetta Chimica Italiana, 1927, 57, 648; Kirillova et al., Acta Cryst. 2007, E63, m1670) and selenourea (4 mmol) in 5 ml DMSO. A small amount of ethanolamine (0.05 ml) was added to the above solution to prevent the reaction between copper and selenium precursors. A greenish brown solution without any residues was obtained showing complete dissolution of the precursors. Using a ultrasonic spray coater the precursor ink was sprayed over a 1″×1″ molybdenum coated glass substrate kept at 350° C. in a nitrogen environment with oxygen and moisture levels below 5 ppm. An about 2.5 μm thick smooth and crack free CIGS film was prepared by spraying.

The CIGS film was transferred to a graphite box with a lid (not air tight) with a few selenium shots. The graphite box assembly was inserted in an argon filled quartz tube and heated in a tube furnace. The tube furnace was maintained at 550° C. and selenization is performed for 50 min under vacuum. During the selenization process, selenium pellets create selenium vapor over the substrate inside the enclosed graphite box and help to promote grain growth and higher crystallinity in the films.

FIG. 5 shows the x-ray diffraction pattern of sprayed and selenized films. FIG. 5 part (a) shows a broad peak (112) corresponding to nanoparticulate grain size of sprayed CuInₓGa₍₁₋ₓ₎Se₂ film as well as peak from molybdenum substrate. The average grain size of sprayed film was calculated to be 8 nm by Debye-Scherrer formula. Upon selenization the (112) peak width also decreases significantly due to grain growth. Further smaller peaks such as (101), (211) appear showing chalcopyrite phase and higher crystallinity. molybdenum selenide (MoSe₂) peaks can also be observed in FIG. 5 part (b) due to reaction of molybdenum with selenium vapor during selenization. The peak intensity for Mo is smaller after selenization showing that significant amount of the molybdenum is converted to molybdenum selenide.

FIG. 6 shows the scanning electron microscopy (SEM) image of the cross-section of the selenized CIGS layer on molybdenum substrate. Majority of the grains are large columnar type >1 μm in size except for a thin layer in the middle of the film that shows nano size grains. In order to achieve complete grain growth further optimization of selenization time, temperature, and selenium vapor pressure will be needed.

Energy Dispersive Spectrometry (EDS) showed the final composition of the films to be copper poor, i.e. Cu/(Ga+In)˜0.90 and Ga/(Ga+In)˜0.30. Copper poor CIGS films are desirable to achieve high quality photovoltaic-grade semiconductor.

In order to complete the photovoltaic device a CdS layer ˜50 nm was deposited from a solution method described elsewhere (M. A. Contreras et al. Thin Solid Films 2002, 403-404, 204-211). ZnO (50 nm) and ITO (300 nm) thin films were deposited sequentially by RF sputtering. Next a 300 nm thick Ag current collection grid was deposited by DC sputtering.

FIG. 7 shows the IV characteristics under dark and AM1.5 light condition for the solar cell comprising the CIGS thin film made from hydroxamato based precursor ink. The device characteristics were as follows: energy conversion efficiency, η or power conversion efficiency PCE=11.01%, fill factor FF=0.58, open circuit voltage V_{oc}=0.606V, and short circuit current density J_{sc}=31.39 mA/cm².

The efficiency of the solar cells can be improved further by optimization of annealing time/temperature, controlling Se/S vapor pressure during sulfurization or selenization, introducing gallium gradients in the CIGS film, optimization of Na and other dopants, optimization of other layers of the device.

### DESCRIPTION OF THE DRAWINGS

The invention will be more fully explained and illustrated by the above description and examples when taken in conjunction with the accompanying drawings (FIGS. 1 to 7).

FIG. 1. TGA traces of a: isobutyrohydroxamato (iBuH) metal complexes; b: pivalohydroxamato (PvH) metal complexes; c: N-methyl-acetohydroxamato (MeAcH) metal complexes. All TG experiments were performed under helium atmosphere at a heating rate of 10° C. min⁻¹.

FIG. 2. X-ray powder diffractograms of pivalohydroxamato metal complexes after annealing at various temperatures.

FIG. 3. X-ray powder diffractograms of isobutyrohydroxamato metal complexes after annealing at various temperatures. The reference spectrum (ICSD) is reproduced on the baseline. For Al(III)iBuH the baseline shows alpha and gamma-Al₂O₃, and the graphs 3 and 4 are in good agreement with the gamma-Al₂O₃ reference spectrum.

FIG. 4. X-Ray diffractograms of ten-layer ITO thin films on alkaline-free glass supports annealed at a: 400° C.; and b: 450° C., measured in reflection mode.

FIG. 5: The graphs shows X-ray diffraction patterns (intensity plotted against diffraction angle 2 theta) of films according to the invention for a) CIGS film sprayed using hydroxamato precursor based ink and b) CIGS film after selenization of sprayed CIGS film by replacement of S by Se, Upon selenization in (b), grain growth occurs as seen from narrowing of (112) peak along with appearance of other chalcopyrite peaks. MoSe₂ formation is also observed upon selenization.

FIG. 6: This figure shows the scanning electron microscopy (SEM) image of the cross-section of the selenized CIGS layer on molybdenum substrate. The majority of the grains is of a large columnar type >1 μm in size, except for a thin layer in the middle of the film that shows nano size grains.

FIG. 7: The graph shows the photovoltaic device response under dark and AM1.5 light condition of a CIGS solar cell described in device Example 20. The device characteristics were as follows: energy conversion efficiency, η or power conversion efficiency PCE=11.01%, fill factor FF=0.58, open circuit voltage V_{oc}=0.606 V, and short circuit current density J_{sc}=31.39 mA/cm².

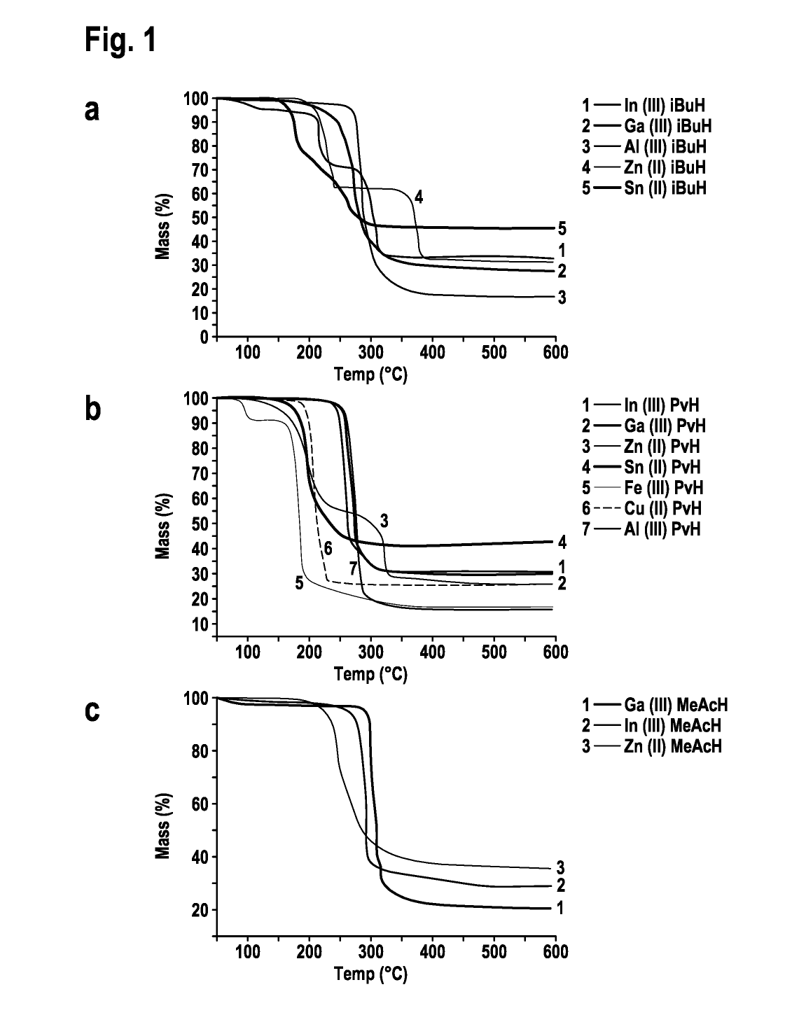

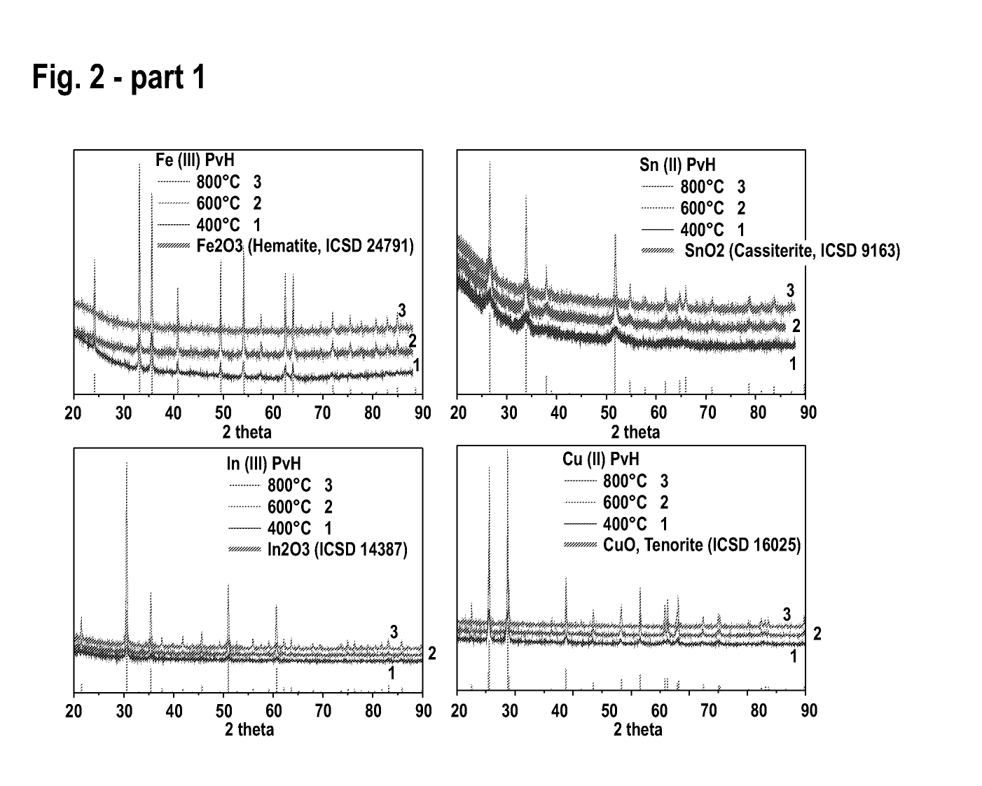

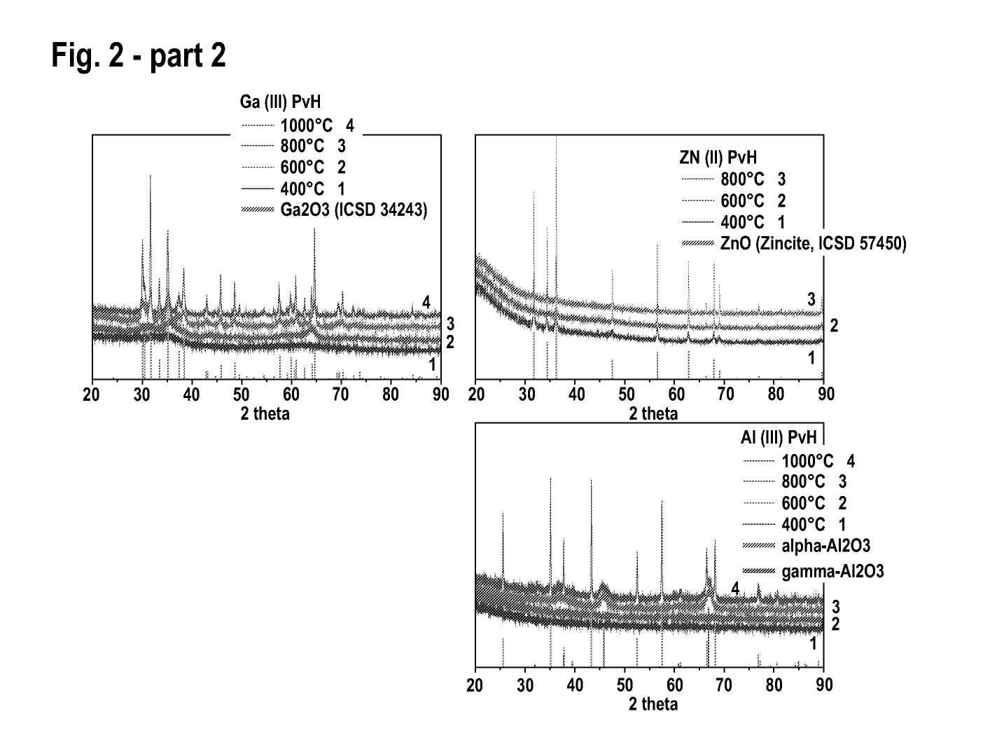

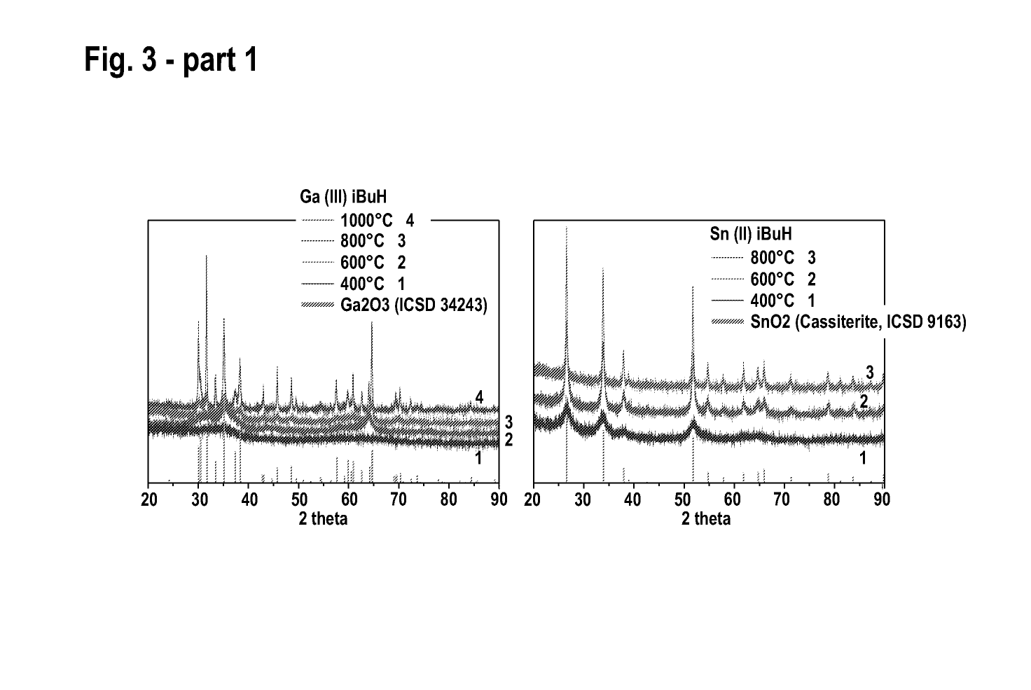

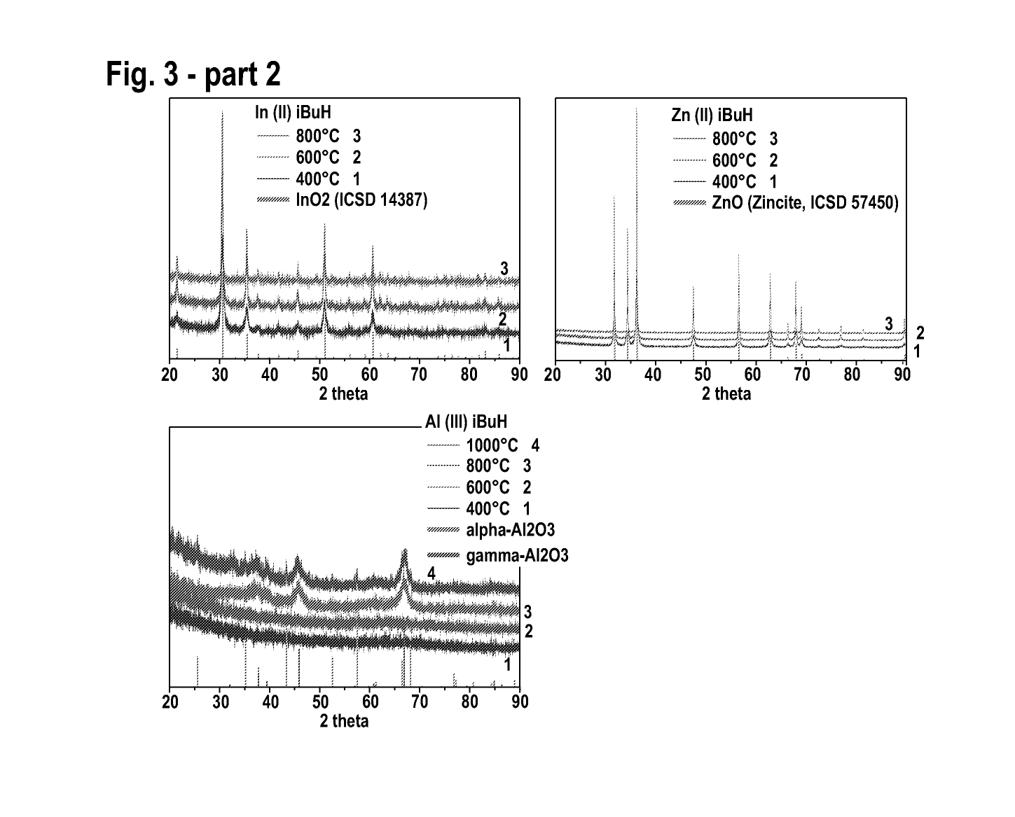

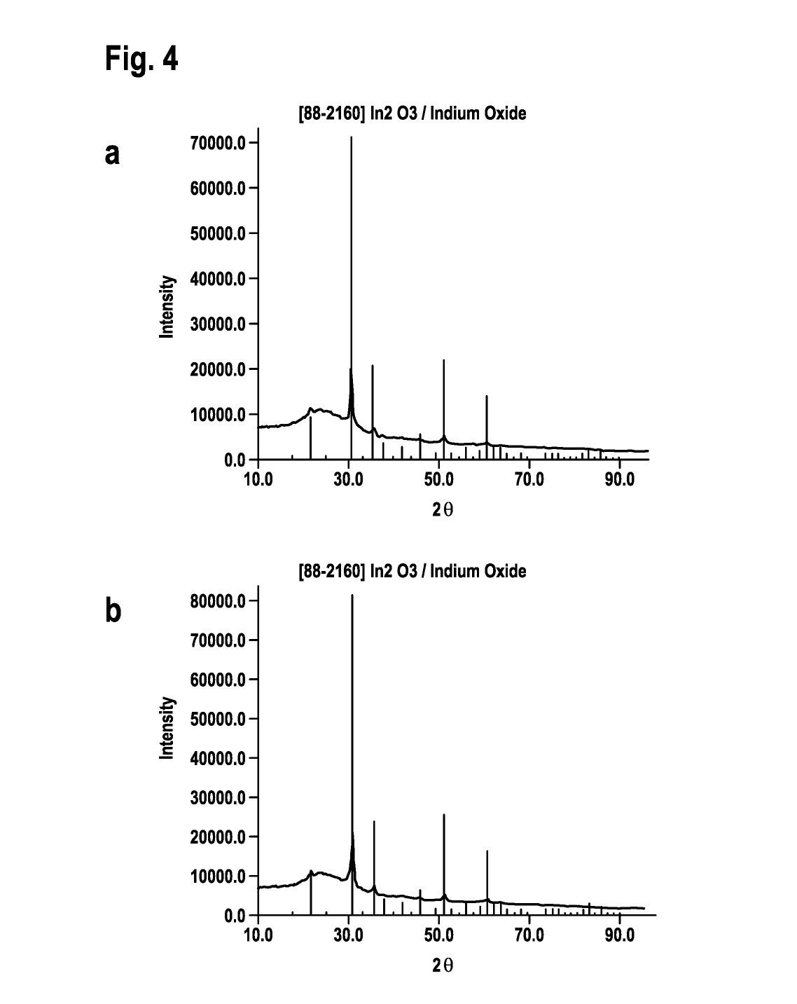

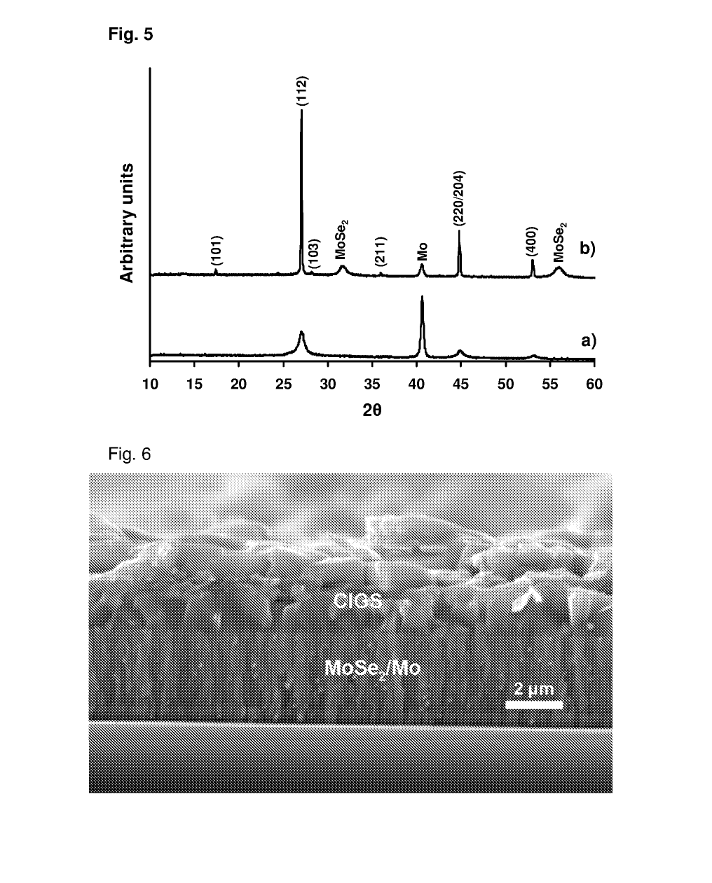

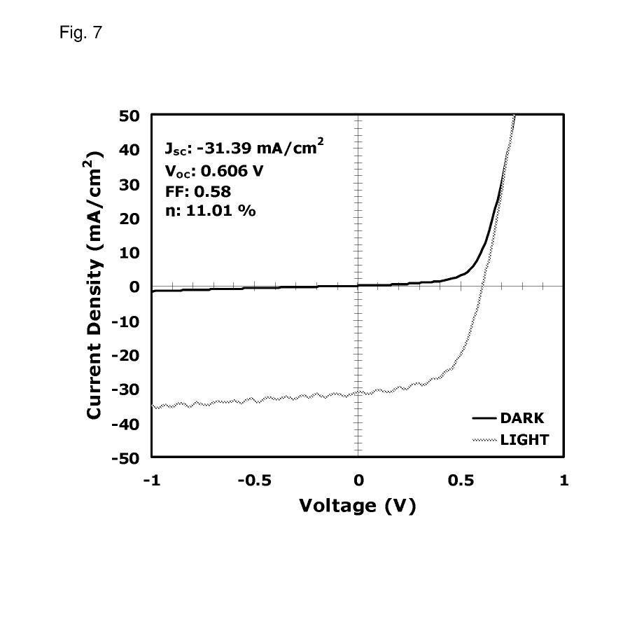

1. Metal complexes comprising hydroxamato ligands, where the ligands are of the structure (L): 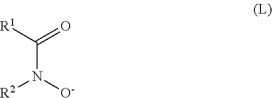
wherein
R¹ is C₁-C₁₅ alkyl, phenyl or benzyl, and
R² is H or C₁-C₆ alkyl,
characterized in that the metal is selected from the elements Ga, In, Zn, Ge, Al or Sn, Y, Lu and Eu.

2. Process for the production of a semiconductor or metal oxide, characterized in that it comprises
a. at least one or more metal complexes are provided as precursors,
at least one of these metal complexes comprises one or more hydroxamato ligands, and
b. the combined precursors are decomposed by heating and/or radiation with formation of the semiconductor or metal oxide.

3. Process according to claim 2, characterized in that in step a. additionally a chalcogen or oxygen source is provided for combination with the one or more precursors.

4. Process according to claim 2, characterized in that the semiconductor is of the I-III-VI₂-type, of the I-VI-type, of the II-VI-type, of the III-VI-type, of the IV-VI-type, or of the I-II-IV-VI₂ type.

5. Process according to claim 2, characterized in that the semiconductor or metal oxide is formed as a film or layer on a substrate.

6. Process according to claim 2, characterized in that the precursors comprise one or more metals selected from aluminium, gallium, zinc, cadmium, copper, germanium, neodymium, ruthenium, magnesium, hafnium, indium, silver, tin and zirconium.

7. Process according to claim 2, characterized in that a further metal precursor not complexed by hydroxamate ligands is used as an additional precursor, which is a metal complex comprising at least one ligand from the class of the ligands bonding by at least one oxygen atom.

8. Process according to claim 7, characterized in that the further metal precursor not complexed by hydroxamate ligands comprises at least one ligand selected from oximates, β-diketonates, carboxylates, alkoxides and all of their derivatives by exchanging hydrogen with other organic groups.

9. Process according to claim 2, characterized in that the precursors are dissolved in a liquid phase.

10. Process according to claim 2, characterized in that the precursors are dissolved in an organic solvent or a mixture of two or more solvents.

11. Process according to claim 2, characterized in that the combined precursors are applied to a substrate as a thin film and decomposed by heat thereafter, optionally repeating the deposition and decomposition steps one or several times.

12. Process according to claim 2, characterized in that the temperature for the decomposition is T≧150° C.

13. Process according to claim 2, characterized in that the metal oxide is copper oxide, indium oxide, gallium oxide, indium oxide, zinc oxide, aluminium oxide, germanium oxide, tin oxide, indium tin oxide, indium zinc oxide, gallium zinc oxide, indium gallium zinc oxide, aluminium zinc oxide, or other mixed metal oxides of the aforementioned metals.

14. Process according to claim 2, characterized in that an additional compound comprising S, Se and/or Te and not comprising a metal is added in or after the process.

15. Process according to claim 2, characterized in that the process includes as a further step a selenization and/or sulfurization step and/or an annealing step after the decomposition of the precursors.

16. Process for the production of an electronic device comprising a layered structure consisting of semiconductor or metal oxide, wherein the layered structure is made by a process according to claim 2.

17. A precursor composition for the formation of a semiconductor or a metal oxide, wherein the semiconductor comprises at least a metal complex comprising a hydroxamato ligand.

18. A composition according to claim 17, characterized in that it is a homogeneous, liquid composition.

19. A composition according to claim 17 comprising at least one metal complex with a hydroxamato ligand and a chalcogen source and that precursor composition can be thermally decomposed to form a solid semiconductor.

20. A composition according to claim 17 comprising at least one metal complex with a hydroxamato ligand and that precursor composition can be thermally decomposed to form a solid metal oxide.
